(19) United States
(12) Patent Application Publication
(10) Pub. No.: US 2011/0031980 A1
(43) Pub. Date: Feb. 10, 2011

(54) SYSTEM FOR MONITORING A TRANSFORMER

(75) Inventors: Michael Kruger, Altach (AT); Ernst Gockenbach, Burgdorf (DE); Hossein Borsi, Hannover (DE)

Correspondence Address: Workman Nydegger;1000 Eagle Gate Tower, 60 East South Temple, Salt Lake City, UT, 84111, US

(73) Assignee: OMICRON ELECTRONICS GMBH, Klaus (AT)

(21) Appl. No.: 12/847,555

(22) Filed: Jul. 30, 2010

(30) Foreign Application Priority Data
Aug. 7, 2009 (EP) EP 09 010 228.6

(51) Int. Cl. G01R 31/06

(52) U.S. Cl. 324/547

(57) ABSTRACT

This invention concerns a system for monitoring a transformer which comprises multiple terminals. The system includes multiple measuring devices and a transformer monitoring device. Each measuring device is arranged adjacently to a terminal of the transformer. Each measuring device includes a housing, a processing unit, a terminal to connect the processing unit to a sensing means to sense an electrical magnitude at the terminal of the transformer, and a data transmission terminal to transmit data between the processing unit and the transformer monitoring device. The transformer monitoring device, which is connected to the multiple measuring devices, is designed to determine, from a combination of the data from the multiple measuring devices, a present state of the transformer.

### CROSS REFERENCE TO RELATED APPLICATIONS

This application claims the benefit of earlier filed European Patent Application No. EP 09 010 228.6 filed Aug. 7, 2009, the disclosure of which is incorporated herein in its entirety.

### BACKGROUND

This invention concerns a system for monitoring a transformer, in particular a system for monitoring the bushings, cable terminals and an active part of the transformer, and a transformer measuring device which is suitable for use in the system for monitoring the transformer.

Transformers, in particular large power transformers in energy transmission networks or network interconnections, are often subjected to strong physical stresses, e.g., high load currents or internal or external short circuits. In this way damage can occur, in particular to insulation, e.g., between individual windings or within one winding, e.g., because of overloading or insulation aging. This damage can have serious consequences for the operational reliability of the transformer. To monitor the state of a transformer, therefore, regular investigations and maintenance are carried out, e.g., investigation of the transformer oil or electrical investigations, e.g., measuring the winding resistances or determining the loss factor.

The object of this invention is to provide improved monitoring for transformers, in order to detect damage to a transformer early and thus to avoid failure of the transformer and detriment to the energy transmission of the energy transmission network.

### SUMMARY

According to this invention, this object is achieved by a measuring device for a transformer according to Claim 1, a system for monitoring a transformer according to Claim 16 and a method for monitoring a transformer according to Claim 20. The dependent claims define preferred and advantageous embodiments of the invention.

According to this invention, a measuring device for a transformer is provided. The measuring device includes a housing, a processing unit, which is housed in the housing, a terminal on the housing to connect the processing unit to a sensing means to sense an electrical magnitude at a terminal of the transformer, and a data transmission terminal to transmit data between the processing unit and an external transformer monitoring device. The measuring device can also include fixing means for attaching the housing to the transformer. Preferably, the measuring device is attached adjacently to the terminal to be monitored. The housing of the measuring device can also be electromagnetically screened, so that the processing unit is protected in the housing from electromagnetic radiation. The data transmission between the processing unit and the external transformer monitoring device can, for example, be by optical data transmission using, for example, an optical waveguide, e.g., a glass fibre or plastic fibre. The measuring device can also include a power supply unit, e.g., a battery or accumulator, to supply electrical energy to the measuring device, and in particular the processing unit.

Since the measuring device can be arranged adjacently to, e.g., immediately next to, the terminal of the transformer, a connection between the processing unit and the sensing means can be minimised, so that disturbances of the sensed electrical magnitude can be avoided. Also, electrical magnitudes can be sensed while the transformer is operating, and preprocessed by the processing unit. The preprocessed data can, for example, be transmitted in digitised form to the transformer monitoring device. Using optical data transmission prevents the data transmission being affected by electromagnetic irradiation, which often occurs around transformers. Since the measuring device includes its own power supply unit, no additional power supply lines from outside the measuring device are required, so that disturbances which are injected via power supply lines can be avoided.

According to one embodiment, the measuring device includes a microphone input for connecting the processing unit to a microphone which is attached to the transformer. In this way the processing unit is capable of, for example, sensing acoustic partial discharge signals of the transformer and transmitting them via the data transmission terminal to the external transformer monitoring device.

According to a further embodiment, the measuring device includes a further microphone input for connecting the processing unit to a microphone which is attached to the terminal of the transformer. In this way the processing unit can also, for example, sense acoustic partial discharge signals which occur in the terminal of the transformer, and transmit them to the transformer monitoring device. In the processing unit, the acoustic signals can be related to the sensed electrical magnitudes, and a result of this correlation can be transmitted to the transformer monitoring device. In this way the data volume to be transmitted can be reduced.

According to a further embodiment, the measuring device includes an electrode, which for example is slab-shaped. The electrode is attached to an outer surface of the housing of the measuring device, in such a way that when the measuring device is attached to the transformer, the electrode, together with, for example, a high voltage line, which is connected to the terminal of the transformer, forms a capacitance. Alternatively, an external electrode can also be attached to the processing unit. The electrode is galvanically disconnected from the housing and connected to the processing unit. The electrode, with the high voltage line, forms a capacitance which can be used as a normal capacitor. The terminal of the transformer can include, for example, a bushing through a transformer housing of the transformer. The sensing means can include a capacitive measuring terminal of this bushing, to sense a capacitance on the bushing, or a metal lining on an insulation of the bushing, to sense a capacitance on the bushing. The capacitance of the normal capacitor and the capacitance of the bushing can form the high voltage capacitors of a measuring bridge for measuring the change of capacitance and the loss factor of the bushing. Monitoring and diagnostics of this bushing are thus possible. A change of the capacitance of the bushing is, for example, a measure of possible damage to insulation, or of a lack of oil in oil bushings. A change of the loss factor can indicate aging of the insulation, for example. The processing unit can be in such a form that it determines the capacitance, a loss factor and/or a partial discharge of the bushing from the sensed electrical magnitude and/or a signal from the electrode.

According to a further embodiment, the terminal of the transformer includes a cable terminal of the transformer. The sensing means includes a high frequency current transmitter, which is connected to a cable, which is connected to the cable terminal of the transformer. Using the high frequency current transmitter, for example, partial discharge signals in the transformer or the cable terminal can be captured. In this way monitoring of the transformer is also possible on the side of the cable terminals.

According to a further embodiment, the measuring device includes a signal generator to feed a test signal into the transformer. The test signal can, for example, be fed in via the sensing means, e.g., via the measuring terminal of the bushing or the high frequency current transmitter. By sensing a signal response at the ends of a winding of the transformer of, for example, the measuring device or transformer monitoring device, a change of a transmission function of the winding can be determined. The change of the transmission function can be a measure of a mechanical change within the winding. In this way, damage in the transformer can be detected early.

According to this invention, a system for monitoring a transformer which comprises multiple terminals is also provided. The system includes multiple measuring devices as described above, each measuring device being arranged adjacently to a terminal of the transformer. The system also includes a transformer monitoring device. The transformer monitoring device is connected to the multiple measuring devices, and is designed to determine, from a combination of the data from the multiple measuring devices, a present state of the transformer. The present state can be, for example, a rated transformation ratio of the transformer, a power of the transformer, a short circuit impedance of the transformer, a transfer function of a winding of the transformer, a partial discharge in the transformer or a partial discharge on one of the multiple terminals. The multiple measuring devices can be connected to the transformer monitoring device via optical data transmission lines, to avoid affecting the transmitted data by electromagnetic irradiation. The multiple terminals of the transformer can include, for example, the phase terminals of the transformer and a neutral conductor of the transformer. By taking measurements on the phase terminals and neutral conductor of the transformer, for example a location of a partial discharge can be determined from different partial discharge measurements on the different phase terminals and the neutral conductor.

According to this invention, a method for monitoring a transformer is also provided. In the method, an electrical magnitude is sensed at a terminal of the transformer, and the sensed electrical magnitude is preprocessed in a measuring device, which is arranged adjacently to the terminal. Data of the preprocessed electrical magnitude are transmitted by the measuring device to a central transformer monitoring device. In the transformer monitoring device, a present state of the transformer is determined from the transmitted data.

The electrical magnitude can comprise, for example, a capacitance between an electrode and a high voltage line which is connected to the terminal of the transformer. The electrode can be, for example, attached oppositely to an outer surface of the housing of the measuring device of the high voltage line. The electrical magnitude can also include a capacitance at the terminal of the transformer. The data can be transmitted from the measuring device to the transformer monitoring device via, for example, optical data transmission lines, so-called optical waveguides. As the measuring device, for example the measuring device described above can be used. The method thus makes it possible to determine a present state of the transformer in operation. The present state can include, for example, a state of an insulation on bushings of the transformer, or a loss factor of the bushings, or partial discharges in the transformer or in the bushings. Since the measuring device is arranged adjacently to the terminal, e.g., a bushing, of the transformer, the electrical magnitudes, e.g., a capacitance or partial discharge signals, can be sensed very precisely, and disturbing irradiation onto these magnitudes can be minimised or avoided. By preprocessing the sensed electrical magnitude, a data quantity to be transmitted can be reduced, and digital transmission, preferably digital optical transmission via optical waveguides, can be carried out, so that falsification of the data by electromagnetic irradiation can be avoided.

According to one embodiment, multiple measuring devices are arranged on multiple terminals of the transformer, and the multiple measuring devices each transmit data of preprocessed electrical magnitudes to the central transformer monitoring device. In the central transformer monitoring device, from a combination of the data from the multiple measuring devices, a present state of the transformer is determined. By linking the data from the multiple measuring devices, the state of the transformer can be determined. For example, from multiple partial discharge signals from multiple measuring devices, the partial discharge in the transformer monitoring device can be located.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 shows a power transformer with a bushing and a measuring device according to an embodiment of this invention; and

FIG. 2 shows a power transformer with multiple bushings and multiple cable terminals, and equipped with a system for monitoring the transformer according to an embodiment of this invention.

### DETAILED DESCRIPTION OF THE PREFERRED EMBODIMENTS

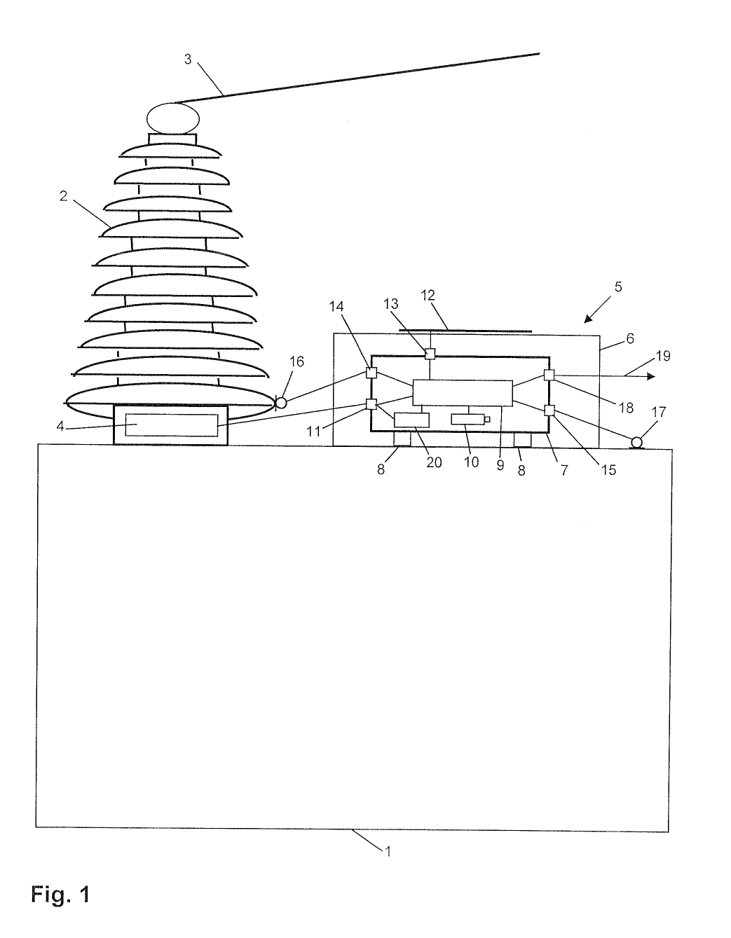

FIG. 1 shows a transformer tank of a transformer 1 with a bushing 2, which connects a high voltage line 3 to the transformer 1. At a bottom end of the bushing 2, a sensing means or sensor 4 is attached. The sensor 4 can be a measuring terminal of the bushing 2, for example. The capacitance between measuring terminal and inner conductor of the bushing 2 can be 100-500 pF, for example. Alternatively, the sensing means 4 can also, for example, be a conductive lining on an insulation of the bushing 2 at the bottom end of the bushing 2, so that a capacitance to the inner conductor of the bushing 2 of, for example, a few 10 s of pF can be achieved.

A measuring device 5 is arranged on the transformer 1, adjacently to the bushing 2. The measuring device 5 includes a housing, which in the shown embodiment comprises a double shell housing with an outer housing 6 and an inner housing 7. The purpose of the outer housing 6 is to protect the measuring device from climatic effects and insolation, whereas the inner housing 7 is provided with electromagnetic screening, to protect a processing unit 9 within the inner housing 7 from electromagnetic radiation from, for example, the high voltage line 3 and the transformer 1. The outer housing 6 can be implemented in partly open form, to support cooling of the measuring device 5. The housing 6, 7 is fixed by fixing means 8 on the transformer 1, adjacently to the bushing 2. Next to the processing unit 9, within the inner housing 7, is a battery 10 to supply the processing unit 9. The inner housing 7 and the outer housing 6 are connected electrically to the transformer 1 and thus earthed.

On the top of the outer housing 6 there is, galvanically disconnected from the outer housing 6, a (for example slab-shaped) electrode or a guard ring electrode, opposite the high voltage line 3. The electrode 12, with the high voltage line 3, forms a capacitance, which is used as a normal capacitor. Via an electrode terminal 13, the electrode 12 is connected to the processing unit 9. Additionally, on the inner housing 7, a sensor terminal 11, via which the processing unit 9 is connected to the sensor 4 on the bushing 2, is provided. The processing unit 9 is thus capable of sensing electrical signals of the normal capacitor, i.e., of the combination of electrode 12 and high voltage line 3, and electrical signals of the capacitive sensor 4 of the bushing 2. The capacitance of the normal capacitor and the capacitance of the bushing 2 form the high voltage capacitors a measuring bridge for measuring the change of capacitance and the loss factor of the bushing 2, to monitor this bushing 2. A change of the capacitance of the bushing 2 can be a measure of possible damage to insulation of the bushing 2, or of a lack of oil in oil bushings. A change of the loss factor indicates aging of the insulation of the bushing 2. To determine the electrical magnitudes of the capacitance of the bushing 2 and the normal capacitor, the processing unit 9 includes various electronic components, e.g., a decoupling impedance, an amplifier and a filter. The processing unit 9 also includes, for example, a central processor, which digitises and further processes the measured electrical magnitudes, and, for example, to transmit via an electrical/optical converter, via a data transmission terminal 18 and an optical waveguide 19 to an external transformer monitoring device.

Thus the processing unit 9 can, for example, output information about a partial discharge or a loss factor of the bushing 2 via the data transmission terminal 18 directly in digitised form. For this purpose, for example, a phase relation and a pulse height of the measured electrical magnitudes can be used.

As well as the described measured magnitudes, the voltage at the bushing 2 can be measured. Since the capacitance of the bushing 2 or the described capacitive measuring electrodes have very small inductances, even rapidly changeable portions of the voltage such as brief voltage peaks or interruptions of the voltage can be sensed. It is impossible to measure these high frequency portions of the voltage using measuring transducers, since these have a transmission range which is restricted to relatively low frequencies.

As well as the voltage at the bushing 2, a current through the bushing 2 can be sensed using built-in current transformers, or using current sensors such as Rogowski coils.

The measuring device 5 also includes two microphone terminals 14, 15, via which two microphones 16, 17 are connected to the processing unit 9. The microphone 16 is attached to the bushing 2, and the microphone 17 is attached to the transformer tank 1. The microphones 16, 17 are used to sense acoustic partial discharge signals, which are preprocessed by the processing unit 9 together with the sensed electrical partial discharge signals, and output via the data transmission terminal 18. Using the microphone 17, it is also possible, for example, to sense noises of a step switch (not shown) in the transformer 1, to monitor a state of the step switch. Depending on the application, further microphones can be used. From the combination of these values, for example, a transformation ratio and a difference from a rated transformation ratio corresponding to the step switch can be determined and monitored. Additionally, using the sensed electrical magnitudes, for example, a power and a short circuit impedance can be determined and monitored.

The measuring device 5 also includes a signal generator 20, which is connected to the sensor 4 via the sensor terminal 11 and controlled by the processing unit 9. Via the sensor 4, the signal generator sends signals into the winding of the transformer. A signal response at the ends of the winding is sensed by further measuring devices, for example. Using this information, the transformer monitoring device determines a change of the transfer function of the winding, representing a measure of the mechanical changes within the winding. In this way, continuous monitoring even of mechanical changes within the transformer is ensured. Additionally, using the signals which are fed in on the bushing 2 from the signal generator 20, calibration for a partial discharge measurement can be carried out.

Finally, the measuring device 5 can have further terminals for, for example, temperature sensors or pressure sensors, for example to determine and monitor an oil temperature of the transformer, an oil pressure in the transformer tank of the transformer 1 and similar.

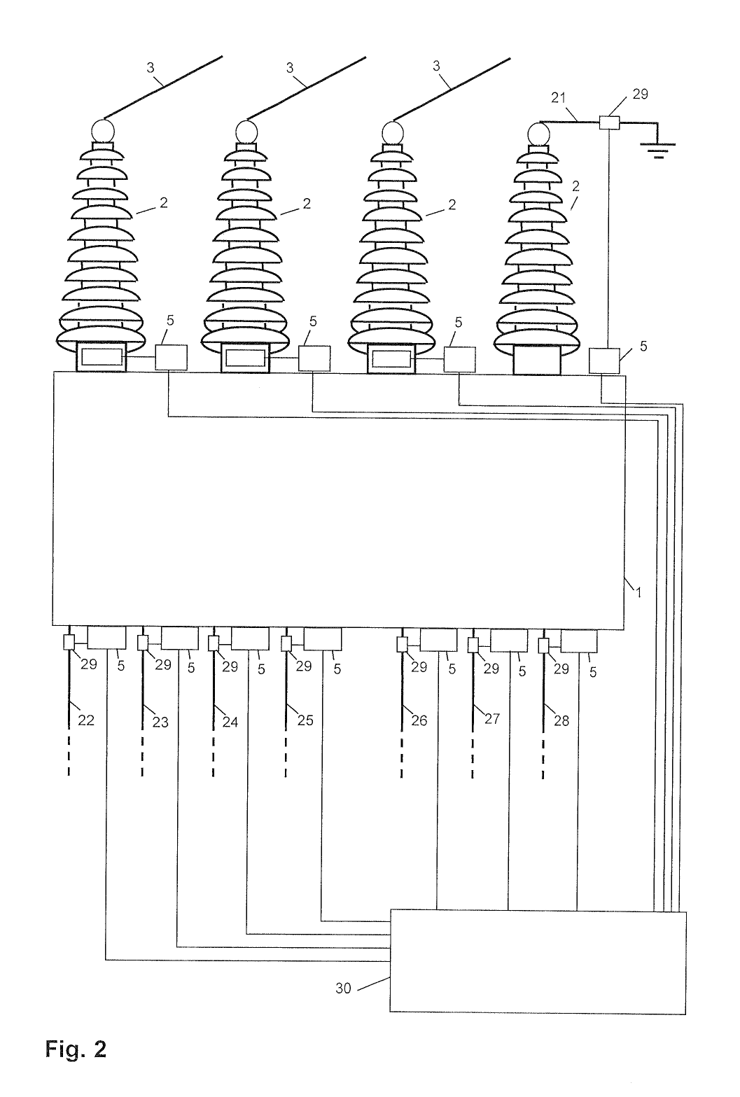

FIG. 2 shows a further embodiment of this invention. A power transformer 1 includes a high voltage winding, a low voltage winding and a tertiary winding. The three phase terminals of the high voltage winding are connected via three bushings 2 to corresponding high voltage lines 3 (in FIG. 2, the three bushings 2 shown on the left). The neutral conductor of the high voltage winding is connected via a further bushing 2 (in FIG. 2, shown on the right) to an earth cable terminal 21. The three phase terminals of the low voltage winding and the neutral conductor of the low voltage winding are connected via cable terminals 22-24 and 25 respectively. The three phase terminals of the tertiary winding are connected via cable terminals 26-28.

The bushings 2 for the three phases of the high voltage winding are monitored, as described above in relation to FIG. 1, using three measuring devices 5, each of which is associated with a bushing 2. A measuring device 5 is also associated with each of the cable terminals 21-28. As the sensor to sense electrical magnitudes at the cable terminals 21-28, high frequency current transmitters 29 are used. A high frequency current transmitter 29 is associated with and connected to each cable terminal 21-28. The high frequency current transmitters 29 are in turn each connected to an associated measuring device 5.

The data transmission terminals 18 of the measuring devices 5 are connected via optical waveguides to a central transformer monitoring device 30. In this way, much information is available to the central transformer monitoring device 30, to monitor the transformer 1 continuously in operation and to detect malfunctions early. Thus, for example, partial discharges both in the bushings 2 and in the transformer 1 itself can be detected and located. Additionally, the loss factor of the bushings 2, the voltage at the bushings, the currents through the bushings and the transmission properties of the windings can be determined. From them, for example, a transformation ratio and a difference from a rated transformation ratio corresponding to a step switch, a power and a short circuit impedance can be calculated and monitored.

Instead of the point-to-point connections of the measuring devices 5 to the transformer monitoring device 30 as shown in FIG. 2, an optical waveguide bus with, for example, two individual conductors (Transmit and Receive), and running from the transformer monitoring device 30 to the input of a first measuring device 5 and from the output of the first measuring device 5 to the input of a second measuring device 5 etc., can be used.

The measuring devices 5 of the two outer phases, for example in FIG. 2 the measuring device 5 of the bushing 2 shown on the left and the measuring device 5 of the bushing 2 shown third from the left, are preferably arranged in such a way that for these two outer phases, identical normal capacitors are formed between the electrodes 12 and the high voltage lines 3. In this way, the effect of different phases is minimised. Additionally, on the basis of the capacitances of the formed normal capacitors, the two outer phases can be diagnosed by comparison. Phase shifts at the electrodes 12 because of adjacent phases or other effects can be compensated for by calibration with precise measurement dividers or transformers, and corrected using, for example, software in the transformer monitoring device 30.

The individual measuring devices 5 can be constructed modularly, so that depending on the intended use they have the corresponding terminals for the corresponding sensors, e.g., the capacitive sensors 4 for the bushings 2 or the microphones 16, 17, or further sensors for temperature sensing or pressure sensing.

The system shown in FIG. 2 thus makes it possible to monitor bushings 2 of transformers 1 in operation, i.e., online, for example by measuring capacitors, loss factors and partial discharges of the bushings 2. The transfer function and the partial discharge behaviour of the windings of the transformer 1 can also be measured and evaluated. Thus the most important electrical parameters of the transformer 1 can be constantly monitored. The measuring device 5 described above, which is tightly attached to the bottom end of the bushing 2, thus ensures high measurement precision of the electrical magnitudes of the bushing 2 and disturbance-free transmission of the preprocessed electrical magnitudes to the transformer monitoring device 30.

What is claimed is:

1. A measuring device for a transformer, comprising:
a housing;
a processing unit, which is housed in the housing;
a terminal at the housing to connect the processing unit to a sensing device to sense an electrical magnitude at a terminal of the transformer, and
a data transmission terminal to transmit data between the processing unit and an external transformer monitoring device.

2. A measuring device according to claim 1, wherein the measuring device comprises fixing means for attaching the housing to the transformer.

3. A measuring device according to claim 1, wherein the data transmission between the processing unit and the external transformer monitoring device comprises optical data transmission.

4. A measuring device according to claim 1, wherein the housing of the measuring device is electromagnetically screened.

5. A measuring device according to claim 1, wherein the measuring device comprises a power supply unit, to supply electrical energy to the measuring device.

6. A measuring device according to claim 1, wherein the measuring device comprises a microphone input for connecting the processing unit to a microphone which is attached to the transformer.

7. A measuring device according to claim 1, wherein the measuring device comprises a microphone input for connecting the processing unit to a microphone which is attached to the terminal of the transformer.

8. A measuring device according to claim 1, wherein the measuring device comprises an input for an oil pressure sensor to connect the processing unit to an oil pressure sensor which is attached to the transformer.

9. A measuring device according to claim 1, wherein the measuring device comprises an electrode, which with the terminal of the transformer forms a capacitance, the electrode being galvanically disconnected from the housing and connected to the processing unit.

10. A measuring device according to claim 1, wherein the measuring device comprises an electrode, the electrode being attached to an outer surface of the housing of the measuring device, in such a way that when the measuring device is attached to the transformer, the electrode, together with a high voltage line, which is connected to the terminal of the transformer, forms a capacitance, the electrode being galvanically disconnected from the housing and connected to the processing unit.

11. A measuring device according to claim 1, wherein the terminal of the transformer comprises a bushing through a transformer housing of the transformer, and wherein the sensing device includes a measuring terminal of the bushing, to sense a capacitance at the bushing.

12. A measuring device according to claim 1, wherein the terminal of the transformer comprises a bushing through a transformer housing of the transformer, and wherein the sensing device includes a metal coating on an insulation of the bushing, to sense a capacitance at the bushing.

13. A measuring device according to claim 1, wherein the terminal of the transformer comprises a bushing through a transformer housing of the transformer, and wherein the processing unit is designed to determine at least one of a group comprising a capacitance, a loss factor, a partial discharge, a voltage, and a current of the bushing.

14. A measuring device according to claim 1, wherein the terminal of the transformer comprises a cable terminal of the transformer, and wherein the sensing device comprises a high frequency current transformer, which is connected to a cable, which is connected to the cable terminal of the transformer.

15. A measuring device according to claim 1, wherein the measuring device comprises a signal generator to feed a test signal into the transformer.

16. A system for monitoring a transformer which comprises multiple terminals, the system comprising:
multiple measuring devices according to claim 1, each measuring device having to be arranged adjacently to a terminal of the transformer, and
a transformer monitoring device, which is connected to the multiple measuring devices, and is designed to determine, from a combination of the data from the multiple measuring devices, a present state of the transformer.

17. A system according to claim 16, wherein the present state comprises at least one of a group comprising a rated transformation ratio of the transformer, a power of the transformer, a short circuit impedance of the transformer, a transfer function of a winding of the transformer, a partial discharge in the transformer, and a partial discharge at one of the multiple terminals.

18. A system according to claim 16, wherein the multiple terminals of the transformer comprise phase terminals of the transformer and a neutral conductor of the transformer.

19. A system according to claim 16, wherein the transformer monitoring device is connected to the multiple measuring devices via optical data transmission lines.

20. A method for monitoring a transformer, the method comprising:
sensing an electrical magnitude at a terminal of the transformer,
preprocessing the sensed electrical magnitude in a measuring device, which is arranged adjacently to the terminal,
transmitting data of the preprocessed electrical magnitude from the measuring device to a transformer monitoring device, and
in the transformer monitoring device, determining a present state of the transformer from the transmitted data.

21. A method according to claim 20, wherein the electrical magnitude comprises a capacitance between an electrode and a high voltage line which is connected to the terminal of the transformer, the electrode being attached at an outer surface of a housing of the measuring device oppositely to the high voltage line.

22. A method according to claim 20, wherein the electrical magnitude includes a capacitance at the terminal of the transformer.

23. A method according to claim 20, wherein the measuring device comprises a measuring device according to claim 1.

24. A method according to claim 20, wherein the data are transmitted from the measuring device to the transformer monitoring device via optical data transmission lines.

25. A method according to claim 20, wherein multiple measuring devices are connected to multiple terminals of the transformer, wherein the multiple measuring devices each transmit data of preprocessed electrical magnitudes to the central transformer monitoring device, and wherein the transformer monitoring device determines, from a combination of the data from the multiple measuring devices, a present state of the transformer.
